(19) United States
(12) Patent Application Publication
(10) Pub. No.: US 2017/0039923 A1
(43) Pub. Date: Feb. 9, 2017

(54) PIXEL ARRAY AND DISPLAY HAVING THE PIXEL ARRAY

(71) Applicant: EVERDISPLAY OPTRONICS (SHANGHAI) LIMITED, SHANGHAI CITY (CN)

(72) Inventor: Yu-Hsiung FENG, SHANGHAI CITY (CN)

(73) Assignee: EVERDISPLAY OPTRONICS (SHANGHAI) LIMITED, SHANGHAI CITY (CN)

(21) Appl. No.: 15/161,394

(22) Filed: May 23, 2016

(30) Foreign Application Priority Data
Aug. 6, 2015 (CN) 201510475763.6

(51) Int. Cl. G09G 3/20; G09G 3/3266; G09G 3/3275; G09G 3/3225

(52) U.S. Cl. CPC G09G 3/2003; G09G 3/3225; G09G 3/3266; G09G 3/3275; G09G 2300/0443; G09G 2300/0452; G09G 2320/0233; G09G 2320/0242

(57) ABSTRACT

The present disclosure relates to a pixel array and a display. The pixel array is composed of a plurality of basic pixel units which are repeated in a row direction and a column direction. Each of the basic pixel units includes m rows and n columns of pixel groups which form x rows and y columns of pixel dots, and each of the groups includes: a first column comprising a first subpixel, a second subpixel and a third subpixel which are arranged in the column direction at a first interval; and a second column comprising a third subpixel, a first subpixel and a second subpixel which are arranged in the column direction at the first interval. The first column is staggered from the second column in the column direction by a second interval; m=n, y=x/2, m, n, x, and y are positive integers, and y is greater than m.

### CROSS-REFERENCE TO RELATED APPLICATIONS

This application claims priority to Chinese Patent Application No. 201510475763.6, filed Aug. 6, 2015, the entire contents of which are incorporated herein by reference.

### TECHNICAL FIELD

The present disclosure relates to display technologies, and more particular to a pixel array, and a display having the pixel array.

### BACKGROUND

Active Matrix Organic Light Emitting Diode (hereinafter referred to as AMOLED) is a new generation display. FIGS. 1(a) to 1(e) are schematic diagrams showing various pixel arrays of an AMOLED display in conventional technologies.

A pixel dot of a conventional pixel array is composed of three subpixels, i.e., a red subpixel, a green subpixel and a blue subpixel. However, existing pixel array designs of AMOLED tend to use arrangements such as PenTile technique. In a PenTile pixel array, a single pixel dot only includes red and green subpixels, or blue and green subpixels. In order to realize all colors, one pixel dot may “borrow” one color of an adjacent pixel dot to form three primary colors. In a row or column direction, each pixel dot shares a subpixel having a color absent in the pixel dot with an adjacent pixel dot so as to cooperatively realize a white display effect.

However, the existing arrangement of pixel array is tend to encounter with zigzags when displaying inclined lines, for example, 45-degree diagonal lines.

### SUMMARY

Embodiments of the present disclosure provide a pixel array and a display having the pixel array to address the defects existing in the conventional technologies, such as zigzags when displaying inclined lines.

According to a first aspect of embodiments of the present disclosure, there is provided a pixel array, composed of a plurality of basic pixel units which are repeated in a row direction and a column direction, wherein each of the basic pixel units includes m rows and n columns of pixel groups which form x rows and y columns of pixel dots, and each of the pixel groups includes:

a first column including a first subpixel, a second subpixel and a third subpixel which are arranged in the column direction at a first interval;

a second column including a third subpixel, a first subpixel and a second subpixel which are arranged in the column direction at the first interval;

wherein the first column is staggered from the second column in the column direction by a second interval;

wherein m=n, y=x/2, m, n, x, and y are positive integers, and y is greater than m.

Optionally, the first subpixel, the second subpixel and the third subpixel have the same width, and the first column is separated from the second column by a third interval which ranges from one third to one second of the width.

Optionally, the first subpixel, the second subpixel and the third subpixel have the same height, and the first interval ranges from one third to one second of the height.

Optionally, the first subpixel, the second subpixel and the third subpixel have the same width, and the second interval ranges from one third to one second of the width.

Optionally, a row interval which refers to a distance between two subpixels at two corresponding positions in two adjacent pixel groups in the row direction is greater than or equal to the width.

Optionally, a column interval which refers to a distance between two subpixels at two corresponding positions in two adjacent pixel groups in the column direction is smaller than a total height of five subpixels.

Optionally, the first interval, the second interval, the third interval, the row interval, and the column interval refer to a distance between edges of the subpixels. Optionally, the first subpixel, the second subpixel and the third subpixel have a rectangular shape, a circular shape, a diamond shape or a regular hexagon shape.

Optionally, the first subpixel is a red subpixel, the second subpixel is a green subpixel and the third subpixel is a blue subpixel; or

the first subpixel is a blue subpixel, the second subpixel is a green subpixel and the third subpixel is a red subpixel.

Optionally, an area of the first subpixel is equal to an area of the third subpixel, and an area of the second subpixel is 75% to 85% of the area of the first subpixel.

According to a second aspect of embodiments of the present disclosure, there is provided a display, including:

a substrate having a pixel region and a non-pixel region, wherein the pixel region has a pixel array as mentioned above; and

a plurality of organic light emitting diodes forming the pixel array in the pixel region and each comprising a first electrode layer, an organic thin film layer and a second electrode layer; and

one or more drivers for driving the pixel array.

Optionally, the one or more drivers comprise a scan driver which provides the same scan signals to the subpixels of the same color in the same row in the pixel array, and a data driver which provides data signals to columns of subpixels of different colors in the pixel array.

Optionally, for each pixel dot in the pixel array, the pixel dot borrows a subpixel in a neighboring pixel dot of the pixel dot to compensate a brightness of the pixel dot.

Optionally, for each pixel dot in the pixel array, the brightness of the pixel dot is compensated according to ratios of respective subpixels in the pixel dot.

As compared with conventional technologies, the technical solution of the present disclosure can save subpixels, and meanwhile overcome the defects of blurring at edges of images in conventional technologies. Also, the present disclosure can improve evaporation accuracy and yields and image resolution. Further, by forming 12*6 pixel dots with 5*5 pixel groups, the image quality issues such as zigzags when displaying inclined lines can be addressed.

### BRIEF DESCRIPTION OF THE DRAWINGS

The above and other features and advantages of the present disclosure will become clearer from the description of exemplary embodiments with reference to drawings.

FIGS. 1(a) to 1(e) are schematic diagrams showing various pixel arrays of an AMOLED display in conventional technologies.

FIG. 2 is a schematic diagram showing a pixel array in related art.

FIG. 3 is a schematic diagram showing a display according to an embodiment of the present disclosure.

FIG. 4(a) is a schematic diagram showing a basic pixel unit according to an embodiment of the present disclosure.

FIG. 4(b) is a schematic diagram showing a local part of a basic pixel unit according to an embodiment of the present disclosure.

FIG. 5 is a schematic diagram showing a local part of a basic pixel unit according to an embodiment of the present disclosure.

FIG. 6 is a schematic diagram showing a local part of a basic pixel unit according to an embodiment of the present disclosure.

FIG. 7 is a schematic diagram showing drivers for presenting color images on a display.

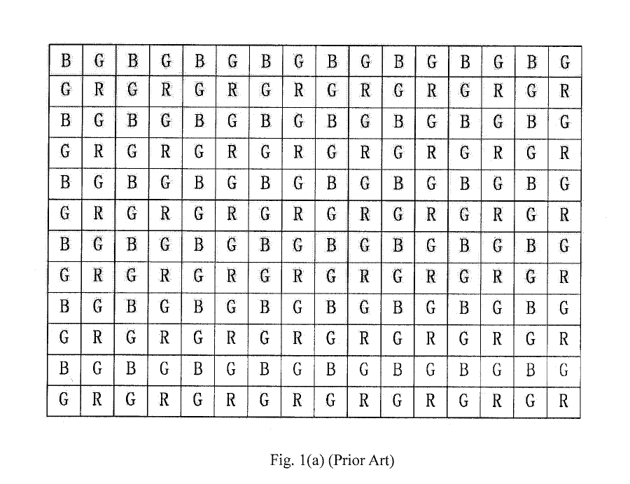

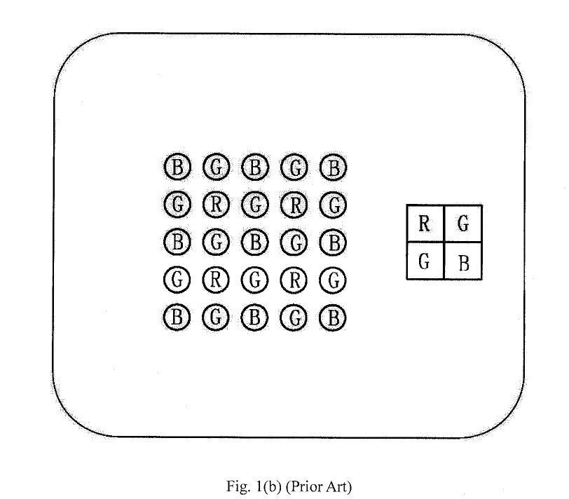

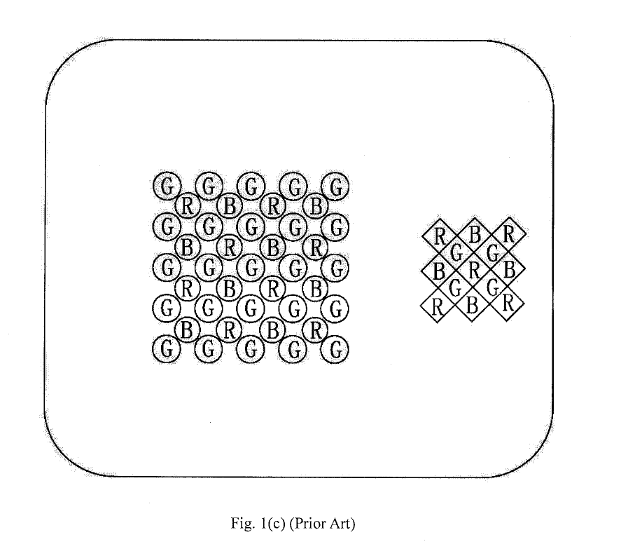

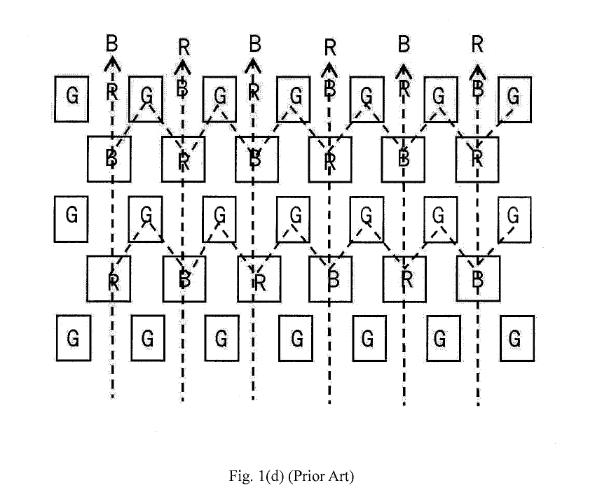

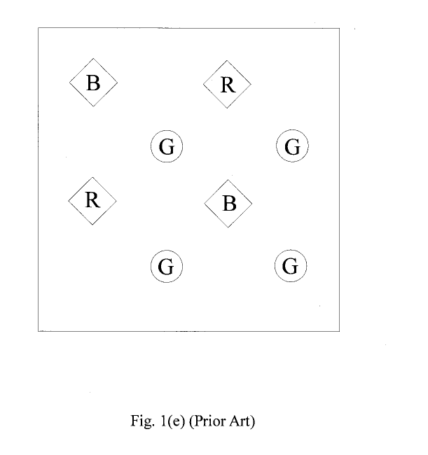

### DETAILED DESCRIPTION

Now, exemplary implementations will be described more comprehensively with reference to the accompanying drawings. However, the exemplary implementations may be carried out in various manners, and shall not be interpreted as being limited to the implementations set forth herein; instead, providing these implementations will make the present disclosure more comprehensive and complete and will fully convey the conception of the exemplary implementations to the ordinary skills in this art. In the drawings, for sake of clarity, thicknesses of regions and layers are exaggerated. Throughout the drawings, the like reference numbers refer to the same or the like structures, and repeated descriptions will be omitted.

The features, structures or characteristics described herein may be combined in one or more embodiments in any suitable manner. In the following descriptions, many specific details are provided to facilitate sufficient understanding of the embodiments of the present disclosure. However, one of ordinary skills in this art will appreciate that the technical solutions in the present disclosure may be practiced without one or more of the specific details, or by employing other methods, elements, materials and so on. In other conditions, well-known structures, materials or operations are not shown or described in detail so as to avoid confusion of respective aspects of the present disclosure.

The drawings of the present disclosure is only for illustrating relative positions, and the sizes at some parts are exaggerated for convenience in understanding, and however the sizes in the drawings do not represent actual proportions.

A pixel array according to an embodiment of the present disclosure may be applied to a display according to an embodiment of the present disclosure; the display according to an embodiment of the present disclosure may have the pixel array according to an embodiment of the present disclosure; and a method for presenting (also called as a rendering method) according to an embodiment of the present disclosure may be applied to the display according to an embodiment of the present disclosure. According to an embodiment, the display according to the present disclosure may be a display of a mobile phone. For example, the display may be an AMOLED display used in a mobile phone.

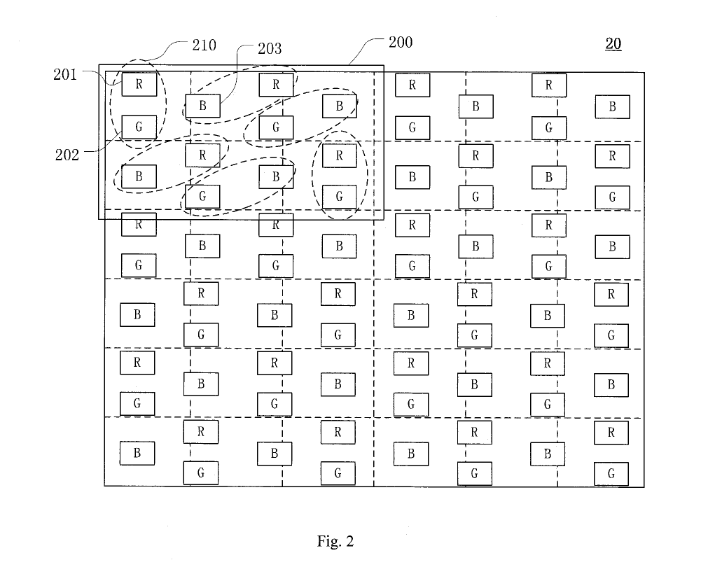

FIG. 2 is a schematic diagram showing a pixel array 20 in related arts. The pixel array is composed of a plurality of basic pixel units 200 which are repeated in a row direction and a column direction. Each basic pixel unit 200 includes 2*3 (i.e., two rows and three columns) pixel dots 210 which are formed by 2*2 (i.e., two rows and two columns) RGB groups each comprising a red subpixel 201, a green subpixel 202, and a blue subpixel 203. Each pixel dot 210 only includes subpixels of two different colors, and thus it may obtain the color absent in the pixel dot itself using corresponding compensation algorithms However, since the pixel array is composed of 2*3 pixel dots 210 which are formed by y 2*2 RGB groups each comprising a red subpixel 201, a green subpixel 202, and a blue subpixel 203, and correspondingly, respective subpixels and the distances therebetween are stretched transversely. Thus, image quality issues such as zigzags when displaying inclined lines occur.

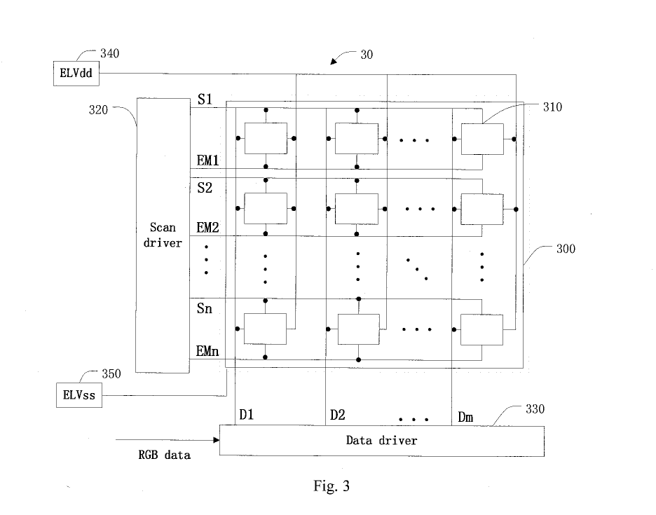

The present disclosure proposes an improved display array to address such issues. The pixel array and the display provided by embodiments of the present disclosure will be described with reference to FIGS. 3 to 8.

FIG. 3 is a schematic diagram showing a display according to an embodiment of the present disclosure. The display is an OLED display 30. Referring to FIG. 3, the OLED display 30 at least includes a display unit 300, a scan driver 320 and a data driver 330. The OLED display 30 may also include other devices and/or elements.

The display unit 300 may include a plurality of pixel dots 310 connected to scan lines (S1 to Sn), light emitting control lines (EM1 to EMn) and data lines (D1 to Dm). The display unit 300 may display an image so as to correspond to a first power source (ELVdd) and a second power source (ELVss). The display unit 300 may further display images corresponding to scan signals provided by the scan lines S1 to Sn, light emitting control signals provided by the light emitting control lines EM1 to EMn, and data signals provided by the data lines D1 to Dm and generated by the data driver 330.

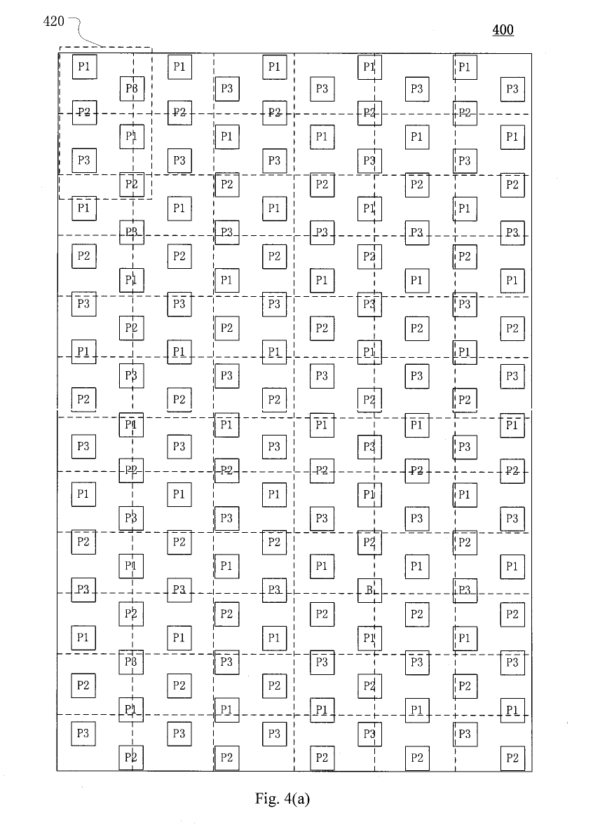

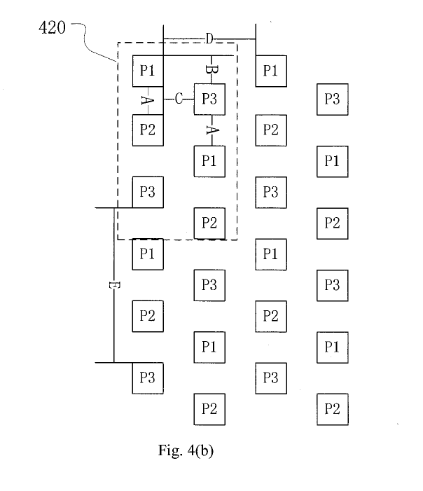

The pixel array provided by embodiments of the present disclosure will be explained in detail with reference to FIGS. 4(a) to 6.

Referring to FIGS. 4(a) and 4(b), the pixel array is composed of a plurality of basic pixel units 400 which are repeated in a row direction and a column direction. Each basic pixel unit 400 includes 5*5 (i.e., five rows and five columns) pixel groups which form 12*6 (i.e., twelve rows and six columns) pixel dots. Each pixel group 420 includes a first column which includes a first subpixel P1, a second subpixel P2 and a third subpixel P3 which are arranged in the column direction at a first interval A, and a second column which includes a third subpixel P3, a first subpixel P1 and a second subpixel P2 which are arranged in the column direction at the first interval A. In an embodiment, the first subpixel P1, the second subpixel P2, and the third subpixel P3 have the same height and width. Based on the above description, the interval between the first subpixel P1 and the second subpixel P2 in the first column is the interval A, and the interval between the second subpixel P2 and the third subpixel P3 in the first column is the interval A as well. The interval between the third subpixel P3 and the first subpixel P1 in the second column is the interval A, and the first subpixel P1 and the second subpixel P2 in the second column is the interval A as well. As shown in FIG. 4(b), the first interval A refers to a distance between edges of adjacent subpixels. For example, the first interval A ranges from one third to one second of the height of a subpixel. The second column and the first column are staggered from each other by a second interval B (as shown in FIG. 4(b), the second column is shifted downwards by a second interval B as compared with the first column). As shown in FIGS. 4(a) and (b), the second interval B refers to a distance between an upper edge of a first subpixel P1 in the first column and an upper edge of a third subpixel P3 in the second column. The second interval B ranges from one third to one second of the width of a subpixel. The first column is separated from the second column by a third interval C. As shown in FIGS. 4(a) and (b), the third interval C refers to a distance between a right edge of each of the subpixels in the first column and a left edge of each subpixels in the second column. The third interval C ranges from one third to one second of the width of a subpixel.

Specifically, a row interval D which refers to a distance between two subpixels at two corresponding positions in two adjacent pixel groups 420 in the row direction is greater than or equal to the width of a subpixel. The row interval D refers to a distance between opposite edges of two subpixels at corresponding positions of two adjacent pixel groups 420 in the row direction. For example, the distance between opposite edges of a first subpixel P1 in the first column of a pixel group 420 and a counterpart subpixel in the first column of a neighboring pixel group 420 which is adjacent to the pixel group 420 a in the row direction is greater than or equal to the width of a subpixel. A column interval E which refers to a distance between two subpixels at two corresponding positions in two adjacent pixel groups 420 in the column direction is smaller than a total height of five subpixels. The column interval E of two subpixels at the corresponding positions of two adjacent pixel groups 420 refers to the distance between the opposite edges of two subpixels at the corresponding positions of two adjacent pixel groups 420 in the column direction. For example, the distance E between opposite edges of a third subpixel P3 in the first column of a pixel group 420 and a counterpart subpixel P3 in the first column of a neighboring pixel group which is adjacent to the pixel group 420 in the column direction is smaller than a total height of five subpixels.

More specifically, as compared with the subpixels in the situation where one pixel group 420 (i.e., two pixel dots) are formed, the first subpixel, the second subpixel and the third subpixel are extended in width and height. The heights and widths of the first, second and third subpixels are six fifths ( 6/5) of the heights and widths of the subpixels in the old pixel arrangement. In some embodiments, the first subpixel is a red subpixel, the second subpixel is a green subpixel, and the third subpixel is a blue subpixel. Alternatively, in other embodiments, the first subpixel is a blue subpixel, the second subpixel is a green subpixel, and the third subpixel is a red subpixel.

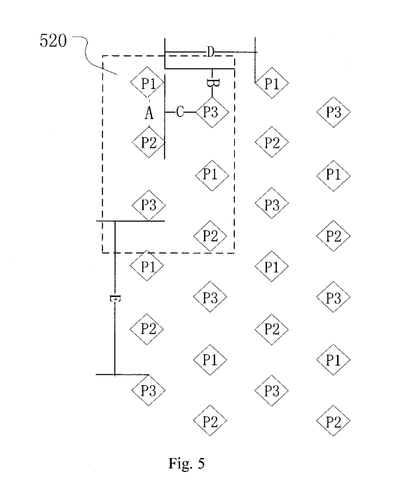

As discussed above, in the basic pixel unit 200 in FIG. 2, 2*2 RGB groups each comprising a red subpixel 201, a green subpixel 202, and a blue subpixel 203 form 2*3 pixel dots 210, and correspondingly the distances between the subpixels are stretched mainly in the horizontal direction. Thus, when displaying inclined line, for example, inclined lines of 45 degree, zigzags may occur. By contrast, in the basic pixel unit 400 in the pixel array in FIGS. 4(a) and 4(b), 5*5 pixel groups 420 form 12*6 pixel dots, which means the distances between the subpixels are stretched in the horizontal and vertical directions, i.e., the distances between the subpixels are stretched equivalently. Thus, when displaying inclined lines, for example, inclined lines of 45 degree, zigzags at the inclined lines can be eliminated. By changing the pixel arrangement, the present disclosure can improve image quality.

Further, because the interval between two adjacent first subpixels P1 in the row direction, the interval between two adjacent second subpixels P2 in the row direction, and the interval between two adjacent third subpixels P3 (for example, the third interval C) are greater than or equal to the width of a subpixel, color mixing does not appear among subpixels in respective pixel dots.

In FIGS. 4(a) and 4(b), a subpixel, a neighboring subpixel on the upper-left thereof and a neighboring subpixel on the lower-right thereof are in the same straight line. Under such situation, in the vertical direction, each of the subpixels is in the middle point between two subpixels in the previous row and the next row.

In the embodiments as shown in FIGS. 4(a) and 4(b), respective subpixel have the same shape (for example, a rectangular shape) and the same size. However, the present disclosure is not limited to this, and the present disclosure may have the following modifications.

FIG. 5 is a schematic diagram showing a local part of a basic pixel unit according to an embodiment of the present disclosure. Specifically, a pixel group is indicated by 520. The difference between the embodiment in FIG. 5 and the embodiment in FIG. 4(b) resides in: the first, the second and the third subpixels have a diamond shape. Specifically, the first interval A, the second interval B, the third interval C, the row interval D and the column interval E refer to the shortest distances between edges of the diamond-shaped subpixels at corresponding positions. In some modified examples, the shapes of the first, the second and the third subpixels may be circle or regular hexagon. Under such situation, the first interval A, the second interval B, the third interval C, the row interval D and the column interval E refer to the shortest distances between edges of subpixels at corresponding positions.

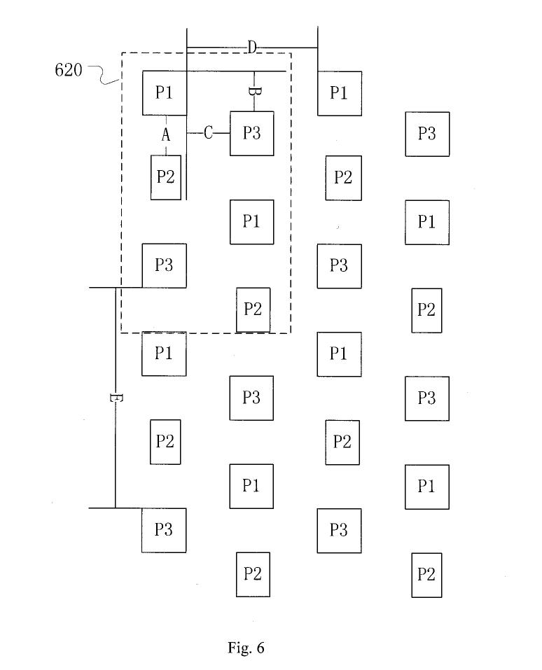

FIG. 6 is a schematic diagram showing a local part of a basic pixel unit according to an embodiment of the present disclosure. Specifically, a pixel group is indicated by 620. As shown in FIG. 6, respective subpixels have a rectangular shape. An area of the each first subpixel P1 is equal to an area of each third subpixel P, and an area of each second subpixel P2 is 75% to 80% of the area of each first subpixel P1. Optionally, the second subpixels P2 are green subpixels. The green subpixels can exert the same functions as other subpixels without having the same size as other subpixels.

The present disclosure is not limited to the embodiment where five rows and five columns of pixel groups form twelve rows and six columns of pixel dots. For example, in the present disclosure, m rows and n columns of pixel groups can form x rows and y columns of pixel dots, where m=n, y=x/2, m, n, x, and y are positive integers, and y is greater than m. As another example, in the present disclosure, four rows and four columns of pixel groups can form ten rows and five columns of pixel dots. Also, one of ordinary skill in this art can devise various modified examples based on the disclosure herein, and detailed descriptions are omitted.

The present disclosure also provides a display, which includes a substrate, organic light emitting diodes and one or more drivers. The substrate has a pixel region and a non-pixel region. The organic light emitting diodes are arranged as an array in the pixel region, and each includes a first electrode layer, an organic thin film layer and a second electrode layer. The one or more drivers drive the pixel array. The pixel array in the pixel region of the display in an embodiment of the present disclosure may be any one of the pixel arrays as shown in FIGS. 4(a) to 6.

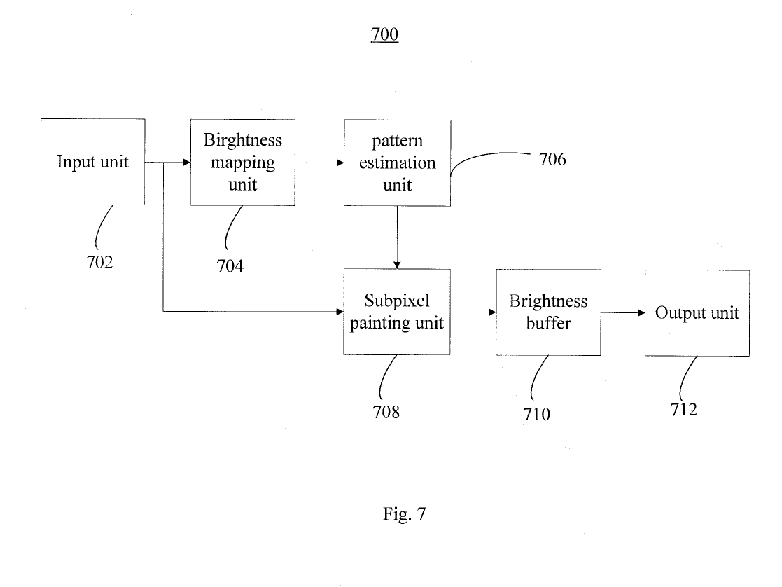

FIG. 7 is a schematic diagram showing a driver 700 for presenting color images on the display according to an embodiment of the present disclosure. The driver 700 is an example of the data driver, and may include an input unit 702, a brightness mapping unit 704, a pattern estimation unit 706, a sub-pixel painting unit 708, a brightness buffer 710 and an output unit 712. The input unit 702 is configured to input image signals representative of the color image to be presented on the display. The brightness mapping unit 704 is configured to generate a brightness map for the color image. The brightness map includes brightness values of each of red color, green color and blue color. The pattern estimation unit 706 is configured to analyze the brightness map to estimate at least one pattern of the color image. The pattern estimation unit 706 is also configured to generate at least one color template for each pattern. The subpixel painting unit 708 is configured to generate an intensity map according to the at least one color template and output the intensity map to the brightness buffer 710. The intensity map includes intensity values of each first subpixel, each second subpixel and each third subpixel of the display. The output unit 712 is configured to output a plurality of voltage signals generated according to the intensity map to the display. In some embodiments, for each pixel dot in the pixel array, the pixel dot borrows a subpixel in a neighboring pixel dot of the pixel dot to compensate a brightness of the pixel dot. In some other embodiments, for each pixel dot in the pixel array, the brightness of the pixel dot is compensated according to ratios of respective subpixels in the pixel dot.

The above detailed descriptions relate to some possible implementations of the present disclosure, and however they are not for limiting the protection scope of the present disclosure, and any equivalent implementations or modifications without departing the spirit of the present disclosure shall fall within the protection scope of the present disclosure.

What is claimed is:

1. A pixel array composed of a plurality of basic pixel units which are repeated in a row direction and a column direction, wherein each of the basic pixel units comprises m rows and n columns of pixel groups which form x rows and y columns of pixel dots, and each of the pixel groups comprises:
a first column comprising a first subpixel, a second subpixel and a third subpixel which are arranged in the column direction at a first interval; and
a second column comprising a third subpixel, a first subpixel and a second subpixel which are arranged in the column at the first interval;
wherein the first column is staggered from the second column in the column direction by a second interval;
wherein m=n, y=x/2, m, n, x, and y are positive integers, and y is greater than m.

2. The pixel array according to claim 1, wherein m=5 and y=6.

3. The pixel array according to claim 1, wherein the first subpixel, the second subpixel and the third subpixel have the same width, and the first column is separated from the second column by a third interval which ranges from one third to one second of the width.

4. The pixel array according to claim 3, wherein the first subpixel, the second subpixel and the third subpixel have the same height, and the first interval ranges from one third to one second of the height.

5. The pixel array according to claim 4, wherein the second interval ranges from one third to one second of the width.

6. The pixel array according to claim 5, wherein a row interval which refers to a distance between two subpixels at two corresponding positions in two adjacent pixel groups in the row direction is greater than or equal to the width.

7. The pixel array according to claim 6, wherein a column interval which refers to a distance between two subpixels at two corresponding positions in two adjacent pixel groups in the column direction is smaller than a total height of five subpixels.

8. The pixel array according to claim 7, wherein the first interval, the second interval, the third interval, the row interval, and the column interval refer to distances between edges of the subpixels.

9. The pixel array according to claim 1, wherein the first subpixel, the second subpixel and the third subpixel have a rectangular shape, a circular shape, a diamond shape or a regular hexagon shape.

10. The pixel array according to claim 1, wherein the first subpixel is a red subpixel, the second subpixel is a green subpixel and the third subpixel is a blue subpixel; or
the first subpixel is a blue subpixel, the second subpixel is a green subpixel and the third subpixel is a red subpixel.

11. The pixel array according to claim 10, wherein an area of the first subpixel is equal to an area of the third subpixel, and an area of the second subpixel is 75% to 85% of the area of the first subpixel.

12. A display comprising:
a substrate having a pixel region and a non-pixel region; and
a plurality of organic light emitting diodes formed on the pixel region as a pixel array and each comprising a first electrode layer, an organic thin film layer and a second electrode layer; and
one or more drivers for driving the pixel array;
wherein the pixel array is composed of a plurality of basic pixel units which are repeated in a row direction and a column direction, wherein each of the basic pixel units comprises m rows and n columns of pixel groups which form x rows and y columns of pixel dots, and each of the pixel groups comprises:
a first column comprising a first subpixel, a second subpixel and a third subpixel which are arranged in the column direction at a first interval; and
a second column comprising a third subpixel, a first subpixel and a second subpixel which are arranged in the column at the first interval;
wherein the first column is staggered from the second column in the column direction by a second interval;
wherein m=n, y=x/2, m, n, x, and y are positive integers, and y is greater than m.

13. The display according to claim 12, wherein the one or more drivers comprise a scan driver which provides the same scan signals to the subpixels of the same color in the same row in the pixel array, and a data driver which provides data signals to columns of subpixels of different colors in the pixel array.

14. The display according to claim 12, wherein for each pixel dot in the pixel array, a subpixel in a neighboring pixel dot of the pixel dot is borrowed to compensate a brightness of the pixel dot.

15. The display according to claim 12, wherein for each pixel dot in the pixel array, brightness of the pixel dot is compensated according to ratios of respective subpixels in the pixel dot.

16. The display according to claim 12, wherein the first subpixel, the second subpixel and the third subpixel have the same width, and the first column is separated from the second column by a third interval which ranges from one third to one second of the width.

17. The display according to claim 16, wherein the first subpixel, the second subpixel and the third subpixel have the same height, and the first interval ranges from one third to one second of the height.

18. The display according to claim 17, wherein a row interval which refers to a distance between two subpixels at two corresponding positions in two adjacent pixel groups in the row direction is greater than or equal to the width.

19. The display according to claim 18, wherein a column interval which refers to a distance between two subpixels at two corresponding positions in two adjacent pixel groups in the column direction is smaller than a total height of five subpixels.

20. The display according to claim 12, wherein an area of the first subpixel is equal to an area of the third subpixel, and an area of the second subpixel is 75% to 85% of the area of the first subpixel.
